(19) United States
(12) Patent Application Publication
(10) Pub. No.: US 2025/0133877 A1
(43) Pub. Date: Apr. 24, 2025

(54) DISPLAY DEVICE

(71) Applicant: Samsung Display Co., LTD., Yongin-si (KR)

(72) Inventors: Young Rok KIM, Yongin-si (KR); Woo Jin CHO, Yongin-si (KR)

(21) Appl. No.: 18/753,844

(22) Filed: Jun. 25, 2024

(30) Foreign Application Priority Data
Oct. 24, 2023 (KR) 10-2023-0142575

(51) Int. Cl. H01L 33/44; H01L 25/075; H01L 33/40; H01L 33/62

(52) U.S. Cl. CPC H10H 20/84; H01L 25/0753; H10H 20/835; H10H 20/857

(57) ABSTRACT

A display device capable of minimizing restrictions on the selection of materials used in a bonding layer includes a substrate, a transistor disposed on the substrate, a planarization layer disposed on the transistor, a first electrode disposed on the planarization layer to be connected to the transistor, an intermediate layer disposed on the first electrode, a second electrode disposed on the intermediate layer, a reflective layer disposed in a trench of the planarization layer and separated from the first electrode and a bonding layer disposed between the inner wall of the trench and the reflective layer.

This application claims priority to Korean Patent Application No. 10-2023-0142575, filed on Oct. 24, 2023, and all the benefits accruing therefrom under 35 U.S.C. § 119, the content of which in its entirety is herein incorporated by reference.

### BACKGROUND

### 1. Technical Field

The present invention relates to a display device, and more particularly, to a display device capable of minimizing restrictions on the selection of materials used in a bonding layer.

### 2. Description of the Related Art

A head mounted display (HMD) is an image display device worn on a user's head in the form of glasses or a helmet so that a focus is formed at a distance close to a user's eyes. For example, the head mounted display may implement virtual reality (VR) or augmented reality (AR).

The head mounted display enlarges and displays an image displayed by a small-sized display device by using a plurality of lenses. Therefore, a display device applied to the head mounted display needs to provide an image of high resolution, for example, an image having resolution of 3000 Pixels per Inch (PPI) or more. To this end, an Organic Light Emitting Diode on Silicon (OLEDoS), which is a small-sized organic light emitting display device of high resolution, is being used as a display device applied to a head mounted display. The OLEDoS is a device that displays images by disposing an organic light emitting diode (OLED) on a semiconductor wafer substrate on which a Complementary Metal Oxide Semiconductor (CMOS) is disposed.

### SUMMARY

Aspects of the invention provide a display device capable of minimizing limits in respect to selection of materials used in a bonding layer.

According to an embodiment, a display device includes a substrate, a transistor on the substrate, a planarization layer on the transistor, a first electrode disposed on the planarization layer to be connected to the transistor, an intermediate layer on the first electrode, a second electrode disposed on the intermediate layer, a reflective layer disposed in a trench of the planarization layer and separated from the first electrode and a bonding layer disposed between the inner wall of the trench and the reflective layer.

In an embodiment, the reflective layer is a floating electrode.

In an embodiment, the reflective layer does not overlap the transistor.

In an embodiment, the display device further includes a connection electrode connecting the transistor and the first electrode.

In an embodiment, the reflective layer and the connection electrode do not overlap each other.

In an embodiment, the bonding layer is in contact with the reflective layer.

In an embodiment, the bonding layer includes at least one of a titanium oxide layer, a titanium nitride layer, an Indium Tin Oxide (ITO) layer, an organic layer and an inorganic layer.

In an embodiment, the display device further includes an insulating layer disposed between the reflective layer and the first electrode.

In an embodiment, the insulating layer includes a first insulating layer disposed on the reflective layer and a second insulating layer disposed on the first insulating layer.

In an embodiment, the first electrode is connected to the connection electrode through a contact hole of the second insulating layer, the first insulating layer, and the planarization layer.

In an embodiment, the connection electrode is connected to one of a source area or a drain area of the transistor.

In an embodiment, the planarization layer includes SiOx.

In an embodiment, the first insulating layer includes SiNx.

In an embodiment, the second insulating layer includes SiOx.

In an embodiment, the area of the first electrode is greater than the area of the reflective layer.

In an embodiment, in a plan view, the edge of the reflective layer is surrounded by the edge of the first electrode.

In an embodiment, the first electrode is directly connected to the connection electrode.

In an embodiment, the first electrode is in direct contact with the connection electrode.

In an embodiment, the reflective layer includes Ag.

In an embodiment, the display device further includes a constant voltage line connected to the reflective layer and transmitting a constant voltage.

In an embodiment, the constant voltage line is disposed between the substrate and the reflective layer.

In the display device, according to an embodiment, limits in respect to selection of materials used on a bonding layer can be minimized.

### BRIEF DESCRIPTION OF THE DRAWINGS

The above and other aspects and features of the invention will become more apparent by describing in detail exemplary embodiments thereof with reference to the attached drawings, in which:

FIG. 1 is an exploded perspective view illustrating a display device, according to an embodiment;

FIG. 2 is a layout view illustrating an example of the display panel shown in FIG. 1, according to an embodiment;

FIG. 3 is a block diagram illustrating a display device, according to an embodiment;

FIG. 4 is an equivalent circuit for a first pixel, according to an embodiment;

FIG. 5 is a plan view illustrating a display device, according to an embodiment;

FIG. 6 is a cross-sectional view illustrating a display device taken along line I-I′ of FIG. 5, according to an embodiment;

FIG. 7 is a cross-sectional view illustrating a display device taken along line I-I′ of FIG. 5, according to another embodiment;

FIG. 8 is a perspective view illustrating a head mounted display device, according to an embodiment;

FIG. 9 is an exploded perspective view illustrating an example of the head mounted display device of FIG. 8, according to an embodiment; and

FIG. 10 is a perspective view illustrating a head mounted display device, according to an embodiment.

### DETAILED DESCRIPTION OF THE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer is referred to as being disposed “on,” “connected to,” or “coupled to” another element, layer or substrate, it can be directly on the other element, layer or substrate, or intervening layers may also be present. The same reference numbers indicate the same components throughout the specification. In the attached figures, the thickness of layers and regions is exaggerated for clarity. To this end, the term “connected” may refer to physical, electrical, and/or fluid connection, with or without intervening elements.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

Features of various embodiments of the invention may be combined partially or totally. As will be clearly appreciated by those skilled in the art, technically various interactions and operations are possible. Various embodiments can be practiced individually or in combination.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described in detail with reference to the accompanying drawings.

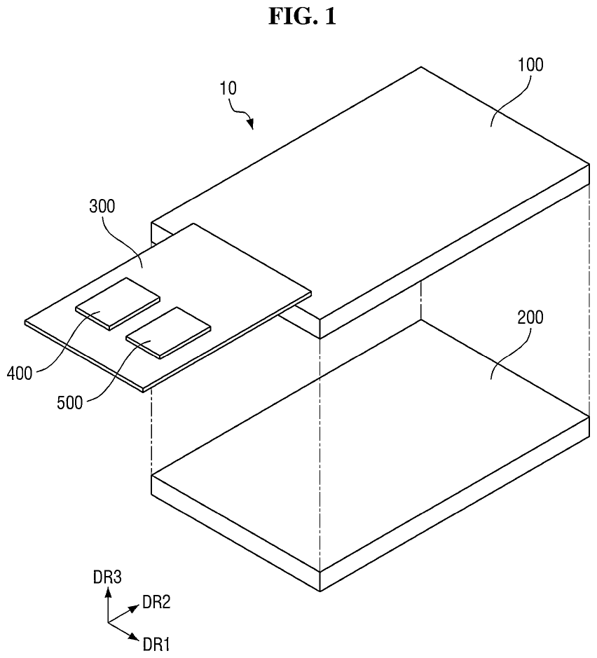

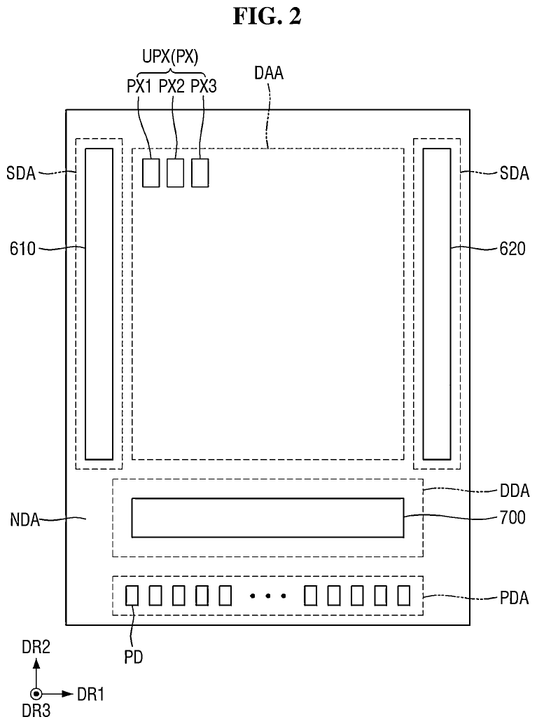

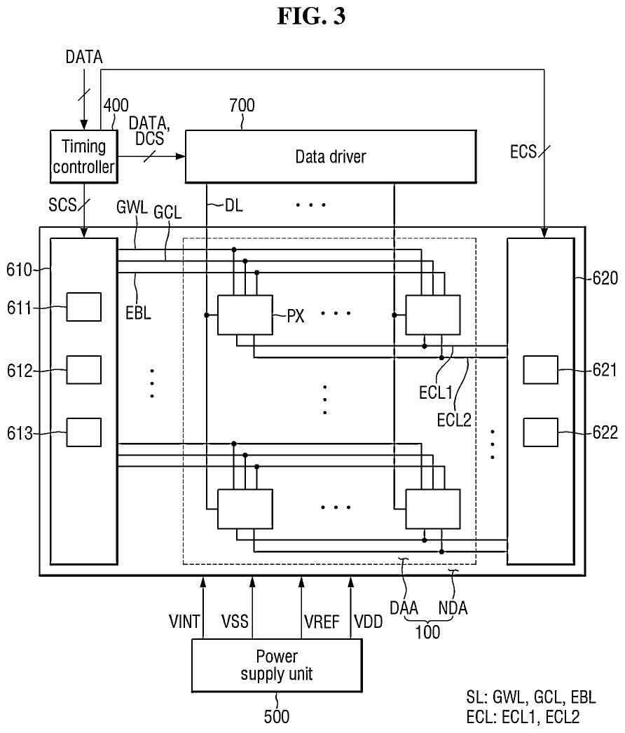

FIG. 1 is an exploded perspective view of a display device, according to an embodiment. FIG. 2 is a layout view illustrating an example of the display panel shown in FIG. 1, according to an embodiment. FIG. 3 is a block diagram illustrating a display device, according to an embodiment.

Referring to FIGS. 1 and 2, a display device 10, according to an embodiment, is a device for displaying a moving image or a still image. The display device 10, according to an embodiment, may be applied to a portable electronic device such as a mobile phone, a smart phone, a tablet personal computer (PC), a mobile communication terminal, an electronic diary, an electronic book, a portable multimedia player (PMP), a navigator and an ultra mobile PC (UMPC). For example, the display device 10 may be applied to a television, a laptop computer, a monitor, a signboard or a display unit of Internet of Things (IoT). Also, the display device 10 may be applied to a smart watch, a watch phone, and a head mounted display (HMD) for implementing virtual reality and augmented reality.

In an embodiment, the display device 10 includes a display panel 100, a heat dissipation layer 200, a circuit board 300, a timing control circuit 400 and a power supply circuit 500.

In an embodiment, the display panel 100 may be formed in a planar shape similar to a rectangular shape. For example, the display panel 100 may have a planar shape similar to a rectangular shape having short sides in a first direction DR1 and long sides in a second direction DR2. A corner where the short side in the first direction DR1 and the long side in the second direction DR2 meet may be rounded to have a predetermined curvature or formed at a right angle. The planar shape of the display panel 100 may be formed to be similar to other polygonal shape, a circular shape or an oval shape without being limited to the rectangular shape. A planar shape of the display device 10 may follow the planar shape of the display panel 100, but the invention is not limited thereto.

In an embodiment, the display panel 100 includes a display area DAA for displaying an image and a non-display area NDA for not displaying an image as shown in FIG. 2.

In an embodiment, the display area DAA includes a plurality of pixels PX, a plurality of scan lines SL, a plurality of emission control lines ECL and a plurality of data lines DL.

In an embodiment, each of the plurality of pixels PX includes a light emitting element for emitting light. The plurality of pixels PX1, PX2 and PX3 may be arranged in the form of a matrix in the first direction DR1 and the second direction DR2. The plurality of scan lines SL and the plurality of emission control lines ECL may be extended in the first direction DR1, and may be disposed in the second direction DR2. The plurality of data lines DL may be extended in the second direction DR2, and may be disposed in the first direction DR1.

In an embodiment, the plurality of scan lines SL include a plurality of write scan lines GWL, a plurality of control scan lines GCL and a plurality of bias scan lines EBL. The plurality of emission control lines ECL include a plurality of first emission control lines ECL1 and a plurality of second emission control lines ECL2.

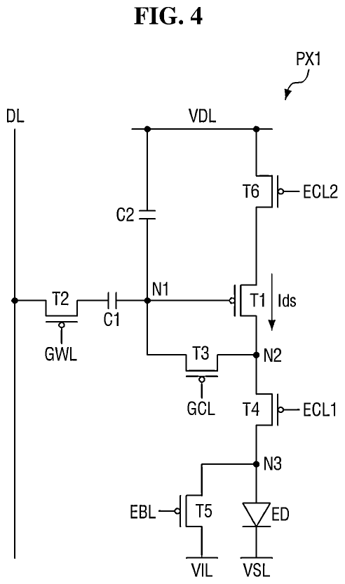

In an embodiment, a plurality of unit pixels UPX include a plurality of pixels PX1, PX2 and PX3. The plurality of pixels PX1, PX2 and PX3 may include a plurality of pixel transistors as shown in FIG. 4, and the plurality of pixel transistors may be formed by a semiconductor process and may be disposed on a semiconductor substrate. For example, the plurality of pixel transistors may be formed of complementary metal oxide semiconductor (CMOS).

In an embodiment, each of the plurality of pixels PX1, PX2 and PX3 may be connected to any one of the plurality of write scan lines GWL, any one of the plurality of control scan lines GCL, any one of the plurality of bias scan lines EBL, any one of the plurality of first emission control lines ECL1, any one of the plurality of second emission control lines ECL2 and any one of the plurality of data lines DL. Each of the plurality of pixels PX1, PX2 and PX3 may receive a data voltage of the data line DL in accordance with a write scan signal of the write scan line GWL and may allow a light emitting element to emit light in accordance with the data voltage.

In an embodiment, the non-display area NDA includes a scan driving area SDA, a data driving area DDA and a pad area PDA.

In an embodiment, the scan driving area SDA may be an area in which a scan driver 610 and an emission driver 620 are disposed. Although FIG. 2 illustrates that the scan driver 610 is disposed at a left side of the display area DAA and the emission driver 620 is disposed at a right side of the display area DAA, the invention is not limited thereto. For example, the scan driver 610 and the emission driver 620 may be disposed at both the left and right sides of the display area DAA.

In an embodiment, the scan driver 610 includes a plurality of scan transistors, and the emission driver 620 includes a plurality of light emitting transistors. The plurality of scan transistors and the plurality of light emitting transistors may be formed by a semiconductor process and may be formed on a semiconductor substrate. For example, the plurality of scan transistors and the plurality of light emitting transistors may be formed of CMOS.

In an embodiment, the scan driver 610 may include a write scan signal output unit 611, a control scan signal output unit 612 and a bias scan signal output unit 613. Each of the write scan signal output unit 611, the control scan signal output unit 612 and the bias scan signal output unit 613 may receive a scan timing control signal SCS from the timing control circuit 400. The write scan signal output unit 611 may generate write scan signals in accordance with the scan timing control signal SCS of the timing control circuit 400 and sequentially output the write scan signals to the write scan lines GWL. The control scan signal output unit 612 may generate control scan signals in accordance with the scan timing control signal SCS and sequentially output the control scan signals to the control scan lines GCL. The bias scan signal output unit 613 may generate bias scan signals in accordance with the scan timing control signal SCS and sequentially output the bias scan signals to bias scan lines EBL.

In an embodiment, the emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals in accordance with the emission timing control signal ECS and sequentially output the first emission control signals to the first emission control lines ECL1. The second emission control driver 622 may generate second emission control signals in accordance with the emission timing control signal ECS and sequentially output the second emission control signals to the second emission control lines ECL2.

In an embodiment, the data driving area DDA may be an area in which a data driver 700 is disposed. The data driver 700 may include a plurality of data transistors, and the plurality of data transistors may be formed by a semiconductor process and may be formed on the semiconductor substrate. For example, the plurality of data transistors may be formed of CMOS.

In an embodiment, the data driver 700 may receive digital video data DATA and a data timing control signal DCS from the timing control circuit 400. The data driver 700 converts the digital video data DATA into analog data voltages in accordance with the data timing control signal DCS and outputs the analog data voltages to the data lines DL. In this case, the plurality of pixels PX1, PX2 and PX3 may be selected by the write scan signal of the scan driver 610, and the data voltages may be supplied to the selected pixels of the plurality of pixels PX1, PX2 and PX3.

In an embodiment, the pad area PDA includes a plurality of pads PD disposed in the first direction DR1. Each of the plurality of pads PD may be exposed without being covered by a cover layer and a polarizing plate.

In an embodiment, the heat dissipation layer 200 may overlap the display panel 100 in a third direction DR3 that is a thickness direction of the display panel 100. The heat dissipation layer 200 may be disposed on one surface of the display panel 100, for example, a rear surface. The heat dissipation layer 200 serves to emit heat generated from the display panel 100. The heat dissipation layer 200 may include a metal layer such as graphite, silver (Ag), copper (Cu) or aluminum (Al), which has high thermal conductivity.

In an embodiment, the circuit board 300 may be electrically connected to the plurality of pads PD of the pad area PDA of the display panel 100 by using a conductive adhesive member such as an anisotropic conductive film. The circuit board 300 may be a flexible printed circuit board or a flexible film, which has a flexible material. Although FIG. 1 illustrates that the circuit board 300 is unfolded, the circuit board 300 may be bent. In this case, one end of the circuit board 300 may be disposed on the rear surface of the display panel 100. One end of the circuit board 300 may be opposite to the other end of the circuit board 300 connected to the plurality of pads PD of the pad area PDA of the display panel 100 by using a conductive adhesive member.

In an embodiment, the timing control circuit 400 may receive digital video data and timing signals from the outside. The timing control circuit 400 may generate the scan timing control signal SCS, the emission timing control signal ECS and the data timing control signal DCS, which are intended for controlling the display panel 100, in accordance with the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

In an embodiment, the power supply circuit 500 may generate a plurality of panel driving voltages in accordance with a power voltage from the outside. For example, the power supply circuit 500 may generate a first driving voltage VSS, a second driving voltage VDD and a third driving voltage VINT and supply them to the display panel 100. The first driving voltage VSS, the second driving voltage VDD and the third driving voltage VINT will be described later with reference to FIG. 4.

In an embodiment, each of the timing control circuit 400 and the power supply circuit 500 may be formed of an integrated circuit (IC) and attached to one surface of the circuit board 300. The scan timing control signal SCS, the emission timing control signal ECS, the digital video data DATA and the data timing control signal DCS of the timing control circuit 400 may be supplied to the display panel 100 through the circuit board 300. The first driving voltage VSS, the second driving voltage VDD and the third driving voltage VINT of the power supply circuit 500 may be supplied to the display panel 100 through the circuit board 300.

FIG. 4 is an equivalent circuit view illustrating a first pixel, according to an embodiment.

In an embodiment and referring to FIG. 4, the first pixel PX1 may be connected to the write scan line GWL, the control scan line GCL, the bias scan line EBL, the first emission control line ECL1, the second emission control line ECL2 and the data line DL. Also, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be higher than the third driving voltage VINT.

In an embodiment, the first pixel PX1 includes a plurality of transistors T1 to T6, a light emitting element ED, a first capacitor C1, and a second capacitor C2.

In an embodiment, the light emitting element ED emits light in accordance with a driving current Ids flowing through a channel of the first transistor T1. The amount of light emitted from the light emitting element ED may be proportional to the driving current Ids. The light emitting element ED may be disposed between the fourth transistor T4 and the first driving voltage line VSL. A first electrode of the light emitting element ED may be connected to a drain electrode of the fourth transistor T4, and a second electrode of the light emitting element ED may be connected to the first driving voltage line VSL. The first electrode of the light emitting element ED may be an anode electrode (or a pixel electrode), and the second electrode of the light emitting element ED may be a cathode electrode (or a common electrode CE). The light emitting element ED may be an organic light emitting diode that includes a first electrode, a second electrode and an organic light emitting layer disposed between the first electrode and the second electrode, but the invention is not limited thereto. For example, the light emitting element ED may be an inorganic light emitting element that includes a first electrode, a second electrode and an inorganic semiconductor disposed between the first electrode and the second electrode. In this case, the light emitting element ED may be a micro light emitting diode.

In an embodiment, the first transistor T1 may be a driving transistor for controlling a source-drain current Ids (hereinafter, referred to as a “driving current”) flowing between a source electrode and a drain electrode in accordance with a voltage applied to a gate electrode. The first transistor T1 includes a gate electrode connected to a first node N1, a source electrode connected to a drain electrode of the sixth transistor T6, and a drain electrode connected to a second node N2.

In an embodiment, the second transistor T2 may be disposed between one electrode of the first capacitor C1 and the data line DL. The second transistor T2 may be turned on by the write scan signal of the write scan line GWL to connect one electrode of the first capacitor C1 to the data line DL. As a result, a data voltage of the data line DL may be applied to one electrode of the first capacitor C1. The second transistor T2 includes a gate electrode connected to the write scan line GWL, a source electrode connected to the data line DL, and a drain electrode connected to one electrode of the first capacitor C1.

In an embodiment, the third transistor T3 may be disposed between the first node N1 and the second node N2. The third transistor T3 is turned on by the write control signal of the write control line GCL to connect the first node N1 to the second node N2. Since the gate electrode and the source electrode of the first transistor T1 are connected to each other, the first transistor T1 may operate like a diode. The third transistor T3 includes a gate electrode connected to the write control line GCL, a source electrode connected to the second node N2, and a drain electrode connected to the first node N1.

In an embodiment, the fourth transistor T4 may be connected between the second node N2 and a third node N3. The fourth transistor T4 is turned on by the first emission control signal of the first emission control line ECL1 to connect the second node N2 to the third node N3. Therefore, the driving current of the first transistor T1 may be supplied to the light emitting element ED. The fourth transistor T4 includes a gate electrode connected to the first emission control line ECL1, a source electrode connected to the second node N2, and a drain electrode connected to the third node N3.

In an embodiment, the fifth transistor T5 may be disposed between the third node N3 and the third driving voltage line VIL. The fifth transistor T5 is turned on by the bias scan signal of the bias scan line EBL to connect the third node N3 to the third driving voltage line VIL. As a result, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

In an embodiment, the sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. As a result, the second driving voltage VDD of the second driving voltage line VDL may be applied to the source electrode of the first transistor T1. The sixth transistor T6 includes a gate electrode connected to the second emission control line ECL2, a source electrode connected to the second driving voltage line VDL, and a drain electrode connected to the source electrode of the first transistor T1.

In an embodiment, the first capacitor C1 is formed between the first node N1 and the drain electrode of the second transistor T2. The first capacitor C1 includes one electrode connected to the drain electrode of the second transistor T2, and the other electrode connected to the first node N1.

In an embodiment, the second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

In an embodiment, the first node N1 is a contact point of the gate electrode of the first transistor T1, the drain electrode of the third transistor T3, the other electrode of the first capacitor C1 and one electrode of the second capacitor C2. The second node N2 is a contact point of the drain electrode of the first transistor T1, the source electrode of the third transistor T3 and the source electrode of the fourth transistor T4. The third node N3 is a contact point of the drain electrode of the fourth transistor T4, the source electrode of the fifth transistor T5 and the first electrode of the light emitting element ED.

In an embodiment, each of the first to sixth transistors T1 to T6, respectively, may be a metal-oxide-semiconductor field effect transistor (MOSFET). For example, each of the first to sixth transistors T1 to T6, respectively, may be a P-type MOSFET, but the invention is not limited thereto. Each of the first to sixth transistors T1 to T6, respectively, may be an N-type MOSFET. In another embodiment, each of some of the first to sixth transistors T1 to T6, respectively, may be a P-type MOSFET, and each of the other transistors may be an N-type MOSFET.

In an embodiment, although FIG. 4 illustrates that the first pixel PX1 includes six transistors T1 to T6 and two capacitors C1 and C2, it should be noted that the equivalent circuit view of the first pixel PX1 is not limited to that shown in FIG. 4. For example, the number of transistors and the number of capacitors of the first pixel PX1 are not limited to those shown in FIG. 4.

Also, in an embodiment, the equivalent circuit view of the second pixel PX2 and the equivalent circuit view of the third pixel PX3 may be substantially the same as the equivalent circuit view of the first pixel PX1 described with reference to FIG. 4. Therefore, the description of the equivalent circuit view of the second pixel PX2 and the equivalent circuit view of the third pixel PX3 will be omitted herein.

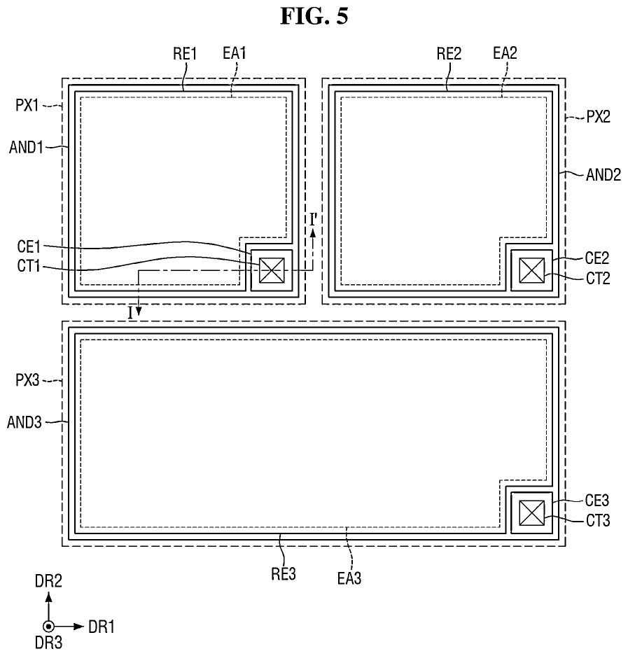

FIG. 5 is a plan view illustrating a display device, according to an embodiment.

In an embodiment and as shown in FIG. 5, the display device 10 may include a first pixel PX1, a second pixel PX2 and a third pixel PX3. The first pixel PX1, the second pixel PX2 and the third pixel PX3 may form one unit pixel. In other words, the unit pixel may include a first pixel PX1, a second pixel PX2 and a third pixel PX3, which are disposed to be adjacent to one another.

In an embodiment, the first to third pixels PX1 to PX3, respectively, of the unit pixel may be pixels for providing light of different colors (or wavelengths). For example, the first pixel PX1 may provide light of a first color, the second pixel PX2 may provide light of a second color, and the third pixel PX3 may provide light of a third color. The first color may be any one of red, green and blue, the second color may be any one color different from the first color among the above-described red, green and blue, and the third color may be any one color different from the first color and the second color among the above-described red, green and blue.

In an embodiment, the first pixel PX1 may include a first anode electrode AND1 and a first reflective layer RE1, the second pixel PX2 may include a second anode electrode AND2 and a second reflective layer RE2, and the third pixel PX3 may include a third anode electrode AND3 and a third reflective layer RE3.

In an embodiment, the first anode electrode AND1, the second anode electrode AND2 and the third anode electrode AND3 may be disposed to be adjacent to one another. For example, the first anode electrode AND1 and the second anode electrode AND2 may be disposed to be adjacent to each other in the first direction DR1, the second anode electrode AND2 and the third anode electrode AND3 may be disposed to be adjacent to each other in the second direction DR2, and the third anode electrode AND3 and the first anode electrode AND1 may be disposed to be adjacent to each other in the second direction DR2.

In an embodiment, the first to third anode electrodes AND1 to AND3 may have different sizes. For example, an area of the third anode electrode AND3 may be larger than an area of the first anode electrode AND1 or an area of the second anode electrode AND2. In another embodiment, an area of the third anode electrode AND3 may be larger than the sum of an area of the first anode electrode AND1 and an area of the second anode electrode AND2. The third pixel PX3 including the third anode electrode AND3 may provide blue light, the first pixel PX1 including the first anode electrode AND1 may provide red light, and the second pixel PX2 including the second anode electrode AND2 may provide green light. As described above, when the third pixel PX3 provides blue light, the first pixel PX1 provides red light and the second pixel PX2 provides green light, the area of the second anode electrode AND2 may be larger than the area of the first anode electrode AND1 and smaller than the area of the third anode electrode AND3.

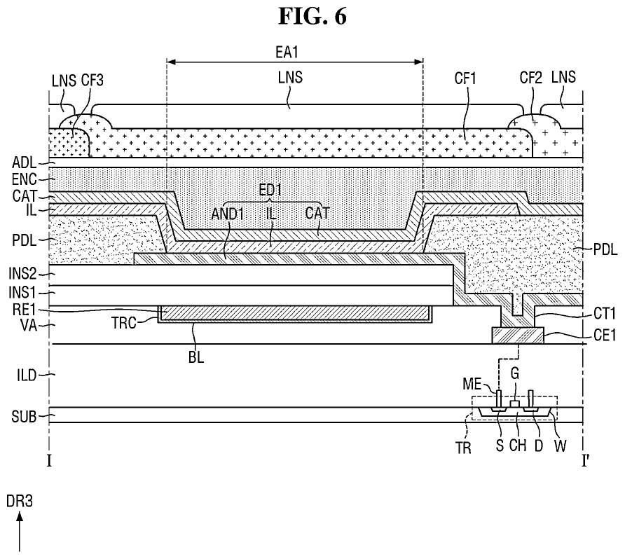

In an embodiment, a portion (e.g., an edge of the first anode electrode AND1) of the first anode electrode AND1, a portion (e.g., an edge of the second anode electrode AND2) of the second anode electrode AND2 and a portion (e.g., an edge of the third anode electrode AND3) of the third anode electrode AND3 may be covered by a pixel defining layer (PDL of FIG. 6) that will be described later. In other words, a portion (e.g., an edge of the first anode electrode AND1) of the first anode electrode AND1, a portion (e.g., an edge of the second anode electrode AND2) of the second anode electrode AND2 and a portion (e.g., an edge of the third anode electrode AND3) of the third anode electrode AND3 may partially overlap the pixel defining layer PDL which defines each of the light emission areas EA1 to EA3 of the pixels PX1 to PX3.

In an embodiment, a first light emission area EA1, a second light emission area EA2 and a third light emission area EA3 may be respectively defined by areas of the first anode electrode AND1, the second anode electrode AND2 and the third anode electrode AND3, which are exposed without being covered by the pixel defining layer PDL. In an embodiment, the first light emission area EA1 may be a light emission area of the first pixel PX1 including the first anode electrode AND1, the second light emission area EA2 may be a light emission area of the second pixel PX2 including the second anode electrode AND2, and the third light emission area EA3 may be a light emission area of the third pixel PX3 including the third anode electrode AND3.

In an embodiment, the first anode electrode AND1 may be connected to the first connection electrode CE1 of the first pixel PX1 through a first contact hole CT1 of the planarization layer (VA in FIG. 6) to be described later, the second anode electrode AND2 may be connected to the second connection electrode CE2 of the second pixel PX2 through a second contact hole CT2 of the planarization layer VA, and the third anode electrode AND3 may be connected to the third connection electrode CE3 of the third pixel PX3 through a third contact hole CT3 of the planarization layer VA. In an embodiment, the first anode electrode AND1 may be directly connected to the first connection electrode CE1, the second anode electrode AND2 may be directly connected to the second connection electrode CE2, and the third anode electrode AND3 may be directly connected to the third connection electrode CE3. In other words, the first anode electrode AND1 may be in direct contact with the first connection electrode CE1, the second anode electrode AND2 may be in direct contact with the second connection electrode CE2, and the third anode electrode AND3 may be in direct contact with the third connection electrode CE3.

In an embodiment, the first reflective layer RE1, the second reflective layer RE2, and the third reflective layer RE3 may be disposed adjacent to each other. For example, in one embodiment, the first reflective layer RE1 and the second reflective layer RE2 may be disposed adjacent to each other in the first direction DR1, the second reflective layer RE2 and the third reflective layer RE3 may be disposed adjacent to each other in the second direction DR2, and the third reflective layer RE3 and the first reflective layer RE1 may be disposed adjacent to each other in the second direction DR2.

In an embodiment, the first to third reflective layers RE1 to RE3, respectively, may have different sizes. For example, the area of the third reflective layer RE3 may be larger than the area of the first reflective layer RE1 or the area of the second reflective layer RE2. In another embodiment, the area of the third reflective layer RE3 may be larger than the sum of the area of the first reflective layer RE1 and the area of the second reflective layer RE2.

In an embodiment, a portion of the first reflective layer RE1 (for example, an edge of the first reflective layer RE1), a portion of the second reflective layer RE2 (for example, an edge of the second reflective layer RE2), and a portion of the third reflective layer RE3 (for example, an edge of the third reflective layer RE3) may be covered by the pixel defining layer PDL. In other words, a portion of the first reflective layer RE1 (for example, an edge of the first reflective layer RE1), a portion of the second reflective layer RE2 (for example, an edge of the second reflective layer RE2), and a portion of the third reflective layer RE3 (for example, an edge of the third reflective layer RE3) may partially overlap the pixel defining layer PDL that defines the light emission areas EA1 to EA3 of the respective pixels PX1 to PX3.

In an embodiment, the first reflective layer RE1, the second reflective layer RE2, and the third reflective layer RE3 may be floating electrodes. For example, the first reflective layer RE1, the second reflective layer RE2, and the third reflective layer RE3 may be electrodes that are not directly connected to any conductive layer and have a floating state.

In an embodiment, the first reflective layer RE1 may overlap the first anode electrode AND1. In a plan view, the area of the first reflective layer RE1 may be smaller than the area of the first anode electrode AND1. In a plan view, the edge of the first reflective layer RE1 may be surrounded by the edge of the first anode electrode AND1. In other words, in a plan view, the first reflective layer RE1 may be completely covered by the first anode electrode AND1.

In an embodiment, the second reflective layer RE2 may overlap the second anode electrode AND2. In a plan view, the area of the second reflective layer RE2 may be smaller than the area of the second anode electrode AND2. In a plan view, the edge of the second reflective layer RE2 may be surrounded by the edge of the second anode electrode AND2. In other words, in a plan view, the second reflective layer RE2 may be completely covered by the second anode electrode AND2.

In an embodiment, the third reflective layer RE3 may overlap the third anode electrode AND3. In a plan view, the area of the third reflective layer RE3 may be smaller than the area of the third anode electrode AND3. In a plan view, the edge of the third reflective layer RE3 may be surrounded by the edge of the third anode electrode AND3. In other words, in a plan view, the third reflective layer RE3 may be completely covered by the third anode electrode AND3.

In an embodiment, the reflective layer and the anode electrode of the same pixel are physically and/or electrically separated from each other. For example, the first reflective layer RE1 and the first anode electrode AND1 of the first pixel PX1 are separated from each other, and the second reflective layer RE2 and the second anode electrode AND2 of the second pixel PX2 are separated from each other, and the third reflective layer RE3 and the third anode electrode AND3 of the third pixel PX3 are separated from each other. In other words, the first anode electrode AND1 may be directly connected to the first connection electrode CE1 without passing through the first reflective layer RE1, the second anode electrode AND2 may be directly connected to the second connection electrode CE2 without passing through the second reflective layer RE2, and the third anode electrode AND3 may be directly connected to the third connection electrode CE3 without passing through the third reflective layer RE3.

FIG. 6 is a cross-sectional view taken along line I-I′ of FIG. 5 illustrating a display device, according to one embodiment.

In an embodiment and as shown in FIG. 6 and FIG. 5, the display device 10 may include a substrate SUB, a transistor TR, an interlayer insulating layer ILD, a planarization layer VA, a first connection electrode CE1, a first reflective layer RE1, a first insulating layer INS1, a second insulating layer INS2, a first anode electrode AND1, a pixel defining layer PDL, an intermediate layer IL, a cathode electrode CAT, an encapsulation layer ENC, an adhesive layer ADL, a first color filter CF1, a second color filter CF2, a third color filter CF3 and a plurality of lenses LNS.

In an embodiment, a substrate SUB may be a silicon substrate, a germanium substrate or a silicon-germanium substrate. The substrate SUB may be a substrate doped with first type impurities.

In an embodiment, a well area W may be disposed on the substrate SUB (or inside the substrate SUB). The well area W may be an area doped with second type impurities. The second type impurities may be different from the first type impurities. In an embodiment, when the first type impurities are p-type impurities, the second type impurities may be n-type impurities. When the first type impurities are n-type impurities, the second type impurities may be p-type impurities.

In an embodiment, a source area S, a drain area D and a channel area CH of a transistor TR may be disposed in the well area W. For example, the source area S (or source electrode) and the drain area D (or drain electrode) of the transistor TR may be disposed in the well area W. Each of the source area S and the drain area D may be an area doped with the first type impurities. A gate electrode G of the transistor TR may overlap the well area W while crossing the same. When viewed in a plan view, the well area W crossing the gate electrode G may be defined as two areas, the source area S may be disposed in any one of the two areas, and the drain area D may be disposed in the other area. In other words, in the well area W, the source area S and the drain area D may be disposed at both sides of the gate electrode G with the gate electrode G interposed therebetween. The channel area CH of the transistor TR may be disposed in an area of the well area W, which overlaps the gate electrode G. The transistor TR shown in FIG. 6 may be, for example, the fourth transistor T4 of FIG. 4.

In an embodiment, the source area S may include a first lightly doped impurity area having an impurity concentration relatively lower than that of the other portions of the source area S. In other words, a portion of the source area S may include impurities of a concentration lower than that of the other portions of the source area S. The drain area D may include a second lightly doped impurity area having an impurity concentration relatively lower than that of the other portions of the drain area D. In other words, a portion of the drain area D may include impurities of a concentration lower than that of the other portions of the drain area D.

In an embodiment, the first lightly doped impurity area and the second lightly doped impurity area may be disposed to be adjacent to the channel area CH of the transistor TR. For example, the first lightly doped impurity area may be disposed to be adjacent to the channel area CH, thereby overlapping a first sidewall disposed at one side of the gate electrode G, and the second lightly doped impurity area may be disposed to be adjacent to the channel area CH, thereby overlapping a second sidewall disposed at the other side of the gate electrode G. As described above, a distance between a heavily doped impurity area of the source area S and a heavily doped impurity area of the drain area D may be increased by the first lightly doped impurity area and the second lightly doped impurity area. As the distance is increased, a length of the channel area CH may be increased. Therefore, punch-through and hot carrier phenomena due to a short channel may be avoided.

In an embodiment, the source area S of each transistor TR may be connected to an anode electrode of a corresponding light emitting element through a metal layer ME. In an embodiment, a source area S of the transistor TR of the first pixel PX1 may be connected to the first anode electrode AND1 through the metal layer ME of the first pixel PX1, a source area S of the transistor TR of the second pixel PX2 may be connected to the second anode electrode AND2 through the metal layer ME of the second pixel PX2, and a source area S of the transistor TR of the third pixel PX3 may be connected to the third anode electrode AND3 through the metal layer ME of the third pixel PX3.

In an embodiment, an interlayer insulating layer ILD may be disposed on the substrate SUB. The interlayer insulating layer ILD may include a plurality of insulating layers stacked along the third direction DR3.

In an embodiment, the first connection electrode CE1, the second connection electrode CE2, and the third connection electrode CE3 may be disposed on the interlayer insulating layer ILD. Each of the connection electrodes CE1 to CE3 may be connected to the metal layer ME through a contact hole penetrating the interlayer insulating layer ILD. In other words, each of the connection electrodes CE1 to CE3 may be connected to the source area S of the corresponding transistor TR through the metal layer ME and the contact hole described above.

In an embodiment, the planarization layer VA may be disposed on the first connection electrode CE1, the second connection electrode CE2, the third connection electrode CE3, and the interlayer insulating layer ILD. For example, the planarization layer VA may be disposed between the substrate SUB and each of the reflective layers RE1 to RE3. Specifically, the planarization layer VA may be disposed between the interlayer insulating layer ILD and each of the reflective layers RE1 to RE3. In an embodiment, the planarization layer VA may include a trench TRC. In an embodiment, the trench TRC may be formed on the upper surface of the planarization layer VA to be disposed between the planarization layer VA and the first insulating layer INS1. In other words, a portion of the upper surface of the planarization layer VA may have a groove that is concavely recessed in a direction opposite to the third direction DR3, and this groove may be defined as the trench TRC of the planarization layer VA. The planarization layer VA may include SiOx.

In an embodiment, a reflective layer may be disposed inside the trench TRC of the planarization layer VA. For example, the first reflective layer RE1 may be disposed inside the trench TRC of the first pixel PX1, the second reflective layer RE2 may be disposed inside the trench TRC of the second pixel PX2, and the third reflective layer RE3 may be disposed inside the trench TRC of the third pixel PX3.

In an embodiment, the reflective layer may not overlap the connection electrode of the pixel on which the reflective layer is disposed. In an embodiment, the first reflective layer RE1 of the first pixel PX1 may not overlap the first connection electrode CE1 of the first pixel PX1 in the third direction DR3, the second reflective layer RE2 may not overlap the second connection electrode CE2 of the second pixel PX2 in the third direction DR3, the third reflective layer RE3 of the third pixel PX3 may not overlap the third connection electrode CE3 of the third pixel PX3 in the third direction DR3.

In an embodiment, the reflective layer may not overlap the transistor TR of the pixel on which the reflective layer is disposed. For example, the first reflective layer RE1 of the first pixel PX1 may not overlap the transistor TR of the first pixel PX1 in the third direction DR3, the second reflective layer RE2 of the second pixel PX2 may not overlap the transistor TR of the second pixel PX2 in the third direction DR3, and the third reflective layer RE3 of the third pixel PX3 may not overlap with the transistor TR of the third pixel PX3 in the third direction DR3.

In an embodiment, the first to third reflective layers RE1 to RE3, respectively, may each include silver (Ag), magnesium (Mg), aluminum (Al), platinum (Pt), palladium (Pd), gold (Au), nickel (Ni), neodymium (Nd), iridium (Ir), chromium (Cr), or an alloy thereof. In an embodiment, each of the first to third reflective layers RE1 to RE3, respectively, may further include a metal oxide layer (e.g., a transparent conductive oxide layer) located above and/or below the metal layer described above. For example, each of the first to third reflective layers RE1 to RE3, respectively, may have a double-layer structure of ITO/Ag, Ag/ITO, ITO/Mg, ITO/MgF, or a triple-layer structure such as ITO/Ag/ITO.

In an embodiment, a bonding layer BL may be disposed along the inner wall of the trench TRC. In an embodiment, the bonding layer BL may be disposed between the inner wall of the trench TRC and the first reflective layer RE1. The bonding layer BL may contact the first reflective layer RE1 and the inner wall of the trench TRC. The bonding layer BL may improve the bonding strength between the first reflective layer RE1 and the planarization layer VA. The bonding layer BL may also be disposed between the inner wall of the trench of the second pixel PX2 and the second reflective layer RE2, and may also be disposed between the inner wall of the trench of the third pixel PX3 and the third reflective layer RE3. Meanwhile, the bonding layer BL is disposed to be separated from the first to third anode electrodes AND1 to AND3.

According to an embodiment, the first to third reflective layers RE1 to RE3, respectively, do not perform the function for electrically connecting the first anode electrode AND1, the second anode electrode AND2 and the third anode electrode AND3 and the first to third connection electrodes CE1 to CE3, respectively. For example, the first to third reflective layers RE1 to RE3, respectively, of one embodiment perform a reflective function, but not perform the function of an electrode that transmits a signal (e.g., data voltage) to the first to third anode electrodes AND1 to AND3, respectively. Accordingly, it is not required to consider the electrical characteristics of the bonding layer BL in contact with the first to third reflective layers RE1 to RE3, respectively. In other words, in a structure where the reflective layer is connected to the anode electrode, a bonding layer must be disposed between the reflective layer and the anode electrode in order to minimize contact resistance between the reflective layer and the anode electrode, and thus, there is a restriction in that the bonding layer must be selected limitedly from materials that have both excellent conductivity and excellent adhesion.

However, according to an embodiment, while each of the first to third reflective layers RE1 to RE3, respectively, perform a reflective function, it does not function as an electrode that transmits signals from the first to third connection electrodes CE1 to CE3, respectively, to the first reflective layer RE1, second reflective layer RE2 and the third reflective layer RE3, respectively, and thus, the bonding layer BL may be selected from various materials capable of maintaining adhesion between the reflective layer and the planarization layer VA. In other words, according to the display device 10 of one embodiment, the restriction in respect to the selection of materials for forming the bonding layer BL can be minimized. For example, the bonding layer BL according to an embodiment may be formed of a non-conductive material in addition to a conductive material (e.g., a metal material). In an embodiment, the bonding layer BL may be formed of a material including a titanium oxide layer (TiOx) or a titanium nitride layer (TiNx). In addition, in an embodiment, the bonding layer BL may be formed as a double layer including indium-tin-oxide (ITO) and a metal layer. Moreover, in an embodiment, the bonding layer BL may be formed of a material including an inorganic layer or an organic layer. In an embodiment, the bonding layer BL may include at least one of a titanium oxide layer, a titanium nitride layer, an ITO, an organic layer, and an inorganic layer. The titanium oxide layer, titanium nitride layer, ITO, organic layer, and inorganic layer described above may have excellent adhesion. Accordingly, the first to third reflective layers RE1 to RE3, respectively, can perform a reflective function and be well adhered to the planarization layer VA through the bonding layer BL.

In an embodiment, the first insulating layer INS1 may be disposed on the first reflective layer RE1, the second reflective layer RE2, the third reflective layer RE3, and the planarization layer VA. For example, the first insulating layer INS1 may be disposed between each reflective layer and each of the anode electrodes AND1 to AND3. The first insulating layer INS1 may include SiNx.

In an embodiment, the second insulating layer INS2 may be disposed on the first insulating layer INS1. For example, the second insulating layer INS2 may be disposed between the first insulating layer INS1 and each of the anode electrodes AND to AND3. The second insulating layer INS2 may include SiOx

In an embodiment, a first light emitting element ED1 of the first pixel PX1, a second light emitting element of the second pixel PX2, and a third light emitting element of the third pixel PX3 may be disposed on the second insulating layer INS2 and the planarization layer VA.

In an embodiment, the first light emitting element ED1 may include a first anode electrode AND1, an intermediate layer IL, and a cathode electrode CAT.

In an embodiment, the first anode electrode AND1 may be disposed on the second insulating layer INS2 and the planarization layer VA. The first anode electrode AND1 may be connected to the first connection electrode CE1 through the first contact hole CT1 penetrating the second insulating layer INS2, the first insulating layer INS1, and the planarization layer VA. Accordingly, the first anode electrode AND1 may be connected to the source area S of the transistor TR provided in the first pixel PX1.

In an embodiment, the second anode electrode AND2 may be disposed on the second insulating layer INS2 and the planarization layer VA. The second anode electrode AND2 may be connected to the second connection electrode CE2 through the second contact hole CT2 penetrating the second insulating layer INS2, the first insulating layer INS1, and the planarization layer VA. Accordingly, the second anode electrode AND2 may be connected to a source area of the transistor provided in the second pixel PX2.

In an embodiment, the third anode electrode AND3 may be disposed on the second insulating layer INS2 and the planarization layer VA. The third anode electrode AND3 may be connected to the third connection electrode CE3 through the third contact hole CT3 penetrating the second insulating layer INS2, the first insulating layer INS1, and the planarization layer VA. Accordingly, the third anode electrode AND3 may be connected to a source area of the transistor provided in the third pixel PX3.

In an embodiment, each of the first to third anode electrodes AND1 to AND3, respectively, may include a transparent conductive material. For example, each of the first to third anode electrodes AND1 to AND3, respectively, may include transparent conductive oxide (TCO). For example, each of the first to third anode electrodes AND1 to AND3, respectively, may include at least one material of indium tin oxide (ITO), indium zinc oxide (IZO), indium gallium oxide (IGO), aluminum zinc oxide (AZO), zinc oxide (ZnO), indium oxide (In₂O₃), indium tin zinc oxide (ITZO), tungsten oxide (WxOx), titanium oxide (TiO₂), or magnesium oxide (MgO), or another transparent conductive material. In an embodiment, each of the first to third anode electrodes AND1 to AND3, respectively, may have a thickness in a range from approximately 70 Å to about 100 Å, but the invention is not limited thereto.

In an embodiment, the first light emitting element ED1 may provide white light. To this end, as an example, the intermediate layer IL of the first light emitting element ED1 may include a plurality of light emitting layers that provide light of different colors, and the plurality of light emitting layers may be stacked in the third direction DR3. In an embodiment the plurality of light emitting layers may include a first light emitting layer, a second light emitting layer, and a third light emitting layer stacked in the third direction DR3. White light may be generated by mixing different lights from the plurality of light emitting layers. Meanwhile, the intermediate layer IL may further include a charge generation layer. The charge generation layer may be disposed between adjacent light emitting layers. As described above, the intermediate layer IL may have a tandem structure including a plurality of light emitting layers and the charge generation layers.

In an embodiment, each of the light emitting layers of the intermediate layer IL may include an organic material to emit a predetermined color. For example, the organic material layer may include a host and a dopant. The organic material layer may include a material for emitting predetermined light and may be formed using a phosphorescent material or a fluorescent material.

In an embodiment, the first light emitting layer may provide light of a first color (e.g., red). To this end, the organic material layer of the first light emitting layer may include a host material containing carbazole biphenyl (CBP) or 1,3-bis (carbazol-9-yl (mCP), and may be a phosphorescent material including a dopant containing at least one selected from PIQIr(acac)(bis(1-phenylisoquinoline) acetylacetonate iridium), PQIr(acac)(bis(1-phenylquinoline) acetylacetonate iridium), PQIr(tris(1-phenylquinoline) iridium) and PtOEP(octaethylporphyrin platinum). In another embodiment, the organic material layer of the first light emitting layer EL1 may be a fluorescent material containing PBD:Eu(DBM)3(Phen) or perylene, but is not limited thereto.

In an embodiment, the second light emitting layer may provide light of a second color (e.g., green). To this end, the organic material layer of the second light emitting layer includes a host material containing CBP or mCP, and may be a phosphorescent material including a dopant material containing Ir(ppy)3(fac tris(2-phenylpyridine) iridium). In another embodiment, the organic material layer of the second light emitting layer may be a fluorescent material containing Alq3(tris(8-hydroxyquinolino)aluminum), but is not limited thereto.

In an embodiment, the third light emitting layer may provide light of a third color (e.g., blue). To this end, the organic material layer of the third light emitting layer may include a host material containing CBP or mCP, and may be a phosphorescent material including a dopant material containing (4,6-F2ppy)2Irpic or L2BD111, but is not limited thereto.

In an embodiment, the second light emitting element of the second pixel PX2 and the third light emitting element of the third pixel PX3 may each have the same configuration as the first light emitting element described above. For example, in an embodiment, the second light emitting element may include a second anode electrode AND2, an intermediate layer IL, and a cathode electrode CAT, and the intermediate layer IL of the second light emitting element may include the first light emitting layer, the second light emitting layer, and the third light emitting layer described above. Similarly, the third light emitting element may include a third anode electrode AND3, an intermediate layer IL, and a cathode electrode CAT, and the intermediate layer IL of the third light emitting element may include the first light emitting layer, the second light emitting layer, and the third light emitting layer described above.

In an embodiment, the pixel defining layer PDL may be disposed on the first anode electrode AND1, the second anode electrode AND2 and the third anode electrode AND3.

In an embodiment, the pixel defining layer PDL may define each light emission area (for example, the first light emission area EA1 of the first pixel PX1, the second light emission area EA2 of the second pixel PX2 and the third light emission area EA3 of the third pixel PX3) of each of the pixels PX1 to PX3. To this end, the pixel defining layer PDL may be disposed to expose a partial area of each of the first anode electrode AND1, the second anode electrode AND2 and the third anode electrode AND3. The pixel defining layer PDL may cover edges of the first anode electrode AND1, the second anode electrode AND2 and the third anode electrode AND3. The pixel defining layer PDL may be formed of an inorganic layer. The pixel defining layer PDL may be formed of an organic layer such as an acryl resin, an epoxy resin, a phenolic resin, a polyamide resin or a polyimide resin.

In an embodiment, the cathode electrode CAT may be disposed on the pixel defining layer PDL and the intermediate layer IL. For example, the cathode electrode CAT may be disposed on the intermediate layer IL of the first pixel PX1, the intermediate layer IL of the second pixel PX2, and the intermediate layer IL of the third pixel PX3 to overlap the first anode electrode AND1, the second anode electrode AND2, the third anode electrode AND3, the first light emission area EA1, the second light emission area EA2, the third light emission area EA3, and the pixel defining layer PDL. In the top emission structure, the cathode electrode CAT may be made of a transparent conductive material (TCO) capable of transmitting light, such as indium tin oxide (ITO) or indium zinc oxide (IZO), or a semi-transmissive conductive material such as magnesium (Mg), silver (Ag) or an alloy of Mg and Ag. When the cathode electrode CAT is made of a semi-transmissive conductive material, light output efficiency may be increased by a microcavity.

In an embodiment, the encapsulation layer ENC may be disposed on the cathode electrode CAT. The encapsulation layer ENC may cover the top and side surfaces of the first light emitting element ED1, the top and side surfaces of the second light emitting element, and the top and side surfaces of the third light emitting element, and may protect the first light emitting element ED1, the second light emitting element, and the third light emitting element. The encapsulation layer ENC may include at least one inorganic layer and at least one organic layer for encapsulating the first light emitting element ED1, the second light emitting element, and the third light emitting element. The encapsulation layer ENC may include at least one inorganic layer to prevent oxygen or moisture from penetrating into the first light emitting element ED1, the second light emitting element, and the third light emitting element. In addition, the encapsulation layer ENC may include at least one organic layer to protect the first light emitting element ED1, the second light emitting element, and the third light emitting element from foreign substances such as dust. For example, the encapsulation layer ENC may include a first inorganic encapsulation layer, an organic encapsulation layer, and a second inorganic encapsulation layer sequentially stacked along the third direction DR3 on the cathode electrode CAT. For example, the first inorganic encapsulation layer may be disposed on the cathode electrode CAT, the organic encapsulation layer may be disposed on the first inorganic encapsulation layer, and the second inorganic encapsulation layer may be disposed on the organic encapsulation layer. Each of the first inorganic encapsulation layer and the second inorganic encapsulation layer may be a multilayer in which one or more inorganic layers selected from a silicon nitride layer, a silicon oxynitride layer, a silicon oxide layer, a titanium oxide layer, and an aluminum oxide layer are alternately stacked. The organic layer may include at least any one of acryl resin, epoxy resin, phenolic resin, polyamide resin, and polyimide resin.

In an embodiment, the adhesive layer ADL may be a layer for adhering the encapsulation layer ENC and the color filter layer (e.g., the first color filter CF1, the second color filter CF2, and the third color filter CF3) together. The adhesive layer ADL may be a double-sided adhesive member. In addition, the adhesive layer ADL may be a transparent adhesive member such as a transparent adhesive or a transparent adhesive resin.

In an embodiment, the color filter layer may include color filters CF1, CF2, and CF3 of different colors. For example, the color filter layer may include a first color filter CF1 disposed to correspond to the first anode electrode AND1 and the first light emission area EA1, a second color filter CF2 disposed to correspond to the second anode electrode AND2 and the second light emission area EA2, and a third color filter CF3 disposed to correspond to the third anode electrode AND3 and the third light emission area EA3.

In an embodiment, the first color filter CF1 may transmit light of the first color, for example, light in the red wavelength band. The red wavelength band may be in a range of approximately 600 nm to about 750 nm. Accordingly, the first color filter CF1 can transmit light of the first color among the light emitted from the first light emission area EA1.

In an embodiment, the second color filter CF2 may transmit light of the second color, for example, light in the green wavelength band. The green wavelength band may be in a range of approximately 480 nm to about 560 nm. Accordingly, the second color filter CF2 can transmit light of the second color among the light emitted from the second light emission area EA2.

In an embodiment, the third color filter CF3 may transmit light of the third color, for example, light in the blue wavelength band. The blue wavelength band may be in a range of approximately 370 nm to 460 nm. Accordingly, the third color filter CF3 can transmit light of the third color among the light emitted from the third light emission area EA3.

In an embodiment, the plurality of lenses LNS may be disposed on the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

In an embodiment, although not shown in the drawings, a filling layer may be further disposed on the plurality of lenses LNS. The filling layer may have a predetermined refractive index such that light travels in the third direction DR3 at an interface between the filling layer and the plurality of lenses LNS. Further, the filling layer may be a planarization layer. The filling layer may be an organic layer such as acrylic resin, epoxy resin, phenolic resin, polyamide resin, or polyimide resin.

In an embodiment, although not shown in the drawings, a cover layer may be further disposed on the filling layer. The cover layer may be a glass substrate or a polymer resin. When the cover layer is a glass substrate, it may be attached onto the filling layer. In this case, the filling layer may serve to bond the cover layer. When the cover layer is a glass substrate SUB, it may serve as an encapsulation substrate. When the cover layer is a polymer resin, it may be directly applied onto the filling layer.

In an embodiment, although not shown in the drawings, a polarizing plate may be further disposed on one surface of the cover layer. The polarizing plate may be a structure for preventing visibility degradation caused by reflection of external light. The polarizing plate may include a linear polarizing plate and a phase retardation film. For example, the phase retardation film may be a λ/4 plate (quarter-wave plate), but the invention is not limited thereto. However, when visibility degradation caused by reflection of external light is sufficiently overcome by the first to third color filters CF1, CF2, and CF3, respectively, the polarizing plate may be omitted.

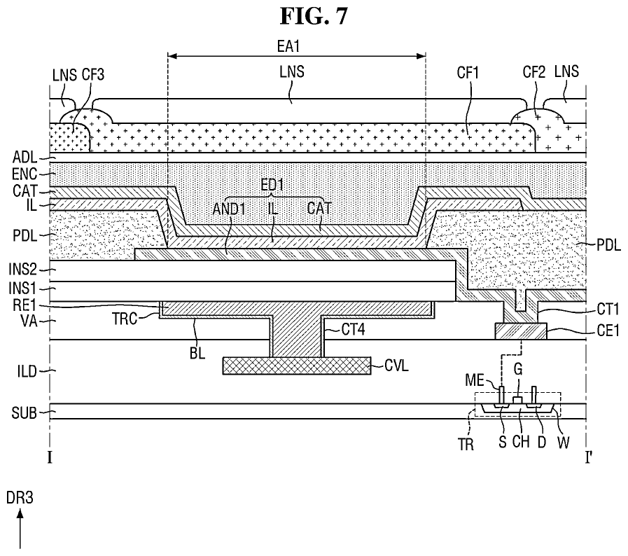

FIG. 7 is a cross-sectional view taken along line I-I′ of FIG. 5 illustrating a display device, according to another embodiment.

The display device of FIG. 7 is a different embodiment from the display device of FIG. 6 in that the first reflective layer RE1 is connected to a constant voltage line CVL, and the following description will mainly focus on this difference.

In an embodiment and as shown in FIG. 7, the constant voltage line CVL transmitting a constant voltage may be disposed on an insulating layer of the interlayer insulating layer ILD. For example, the constant voltage line CVL may be disposed between the substrate SUB and each of the reflective layers RE1 to RE3. The constant voltage line CVL may be connected to the first reflective layer RE1. For example, the first reflective layer RE1 may be connected to the constant voltage line CVL through a fourth contact hole CT4 penetrating the insulating layer of the interlayer insulating layer ILD. Accordingly, the first reflective layer RE1 may receive a constant voltage from the constant voltage line CVL. Therefore, the first reflective layer RE1 may be prevented from floating.

In an embodiment, the constant voltage line CVL may be any one of a first driving voltage line VSL transmitting a first driving voltage VSS, a second driving voltage line VDL transmitting a second driving voltage VDD, and a third driving voltage line VIL transmitting a third driving voltage VINT.

In an embodiment, at least one of the second reflective layer RE2 and the third reflective layer RE3 may be connected to the constant voltage line CVL described above. For example, the first reflective layer RE1, the second reflective layer RE2, and the third reflective layer RE3 may be commonly connected to the constant voltage line CVL.

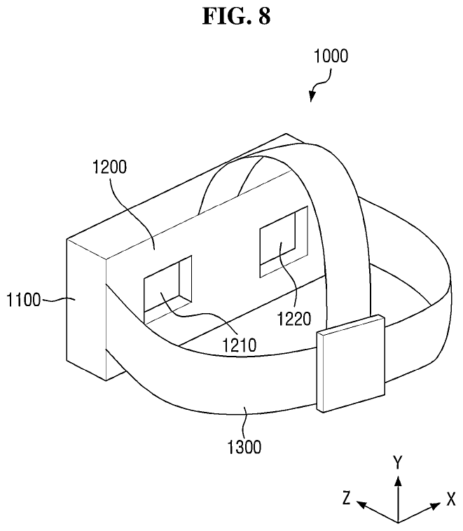

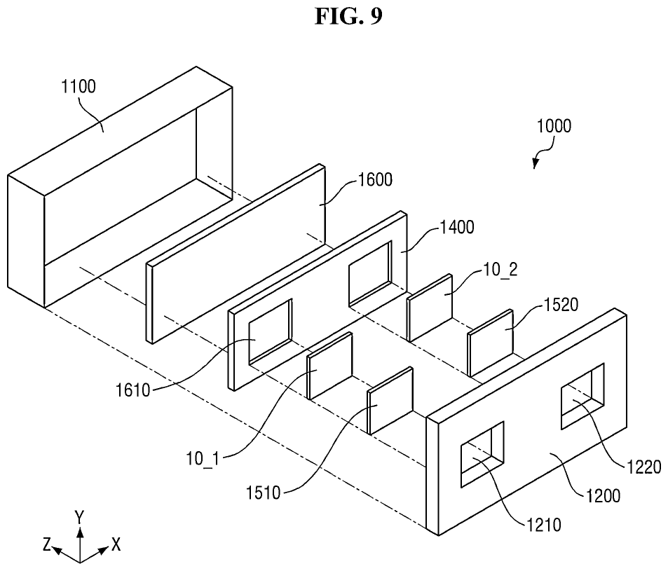

FIG. 8 is a perspective view illustrating a head mounted display device according to one embodiment. FIG. 9 is an exploded perspective view illustrating an example of the head mounted display device of FIG. 8.

In an embodiment and referring to FIGS. 8 and 9, a head mounted display device 1000 includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector 1610.

In an embodiment, the first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 7, description of the first display device 10_1 and the second display device 10_2 will be omitted.

In an embodiment, the first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

In an embodiment, the middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

In an embodiment, the control circuit board 1600 may be disposed between the middle frame 1400 and the display device housing 1100. The control circuit board 1600 may be connected to the first display device 10_1 and the second display device 10_2 through the connector 1610. The control circuit board 1600 may convert an image source inputted from the outside into digital video data DATA, and transmit the digital video data DATA to the first display device 10_1 and the second display device 10_2 through the connector 1610.

In an embodiment, the control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

In an embodiment, the display device housing 1100 serves to accommodate therein the first display device 10_1, the second display device 10_2, the middle frame 1400, the first optical member 1510, the second optical member 1520, the control circuit board 1600, and the connector 1610. The housing cover 1200 is disposed to cover the one open side of the display device housing 1100. The housing cover 1200 may include the first eyepiece 1210 at which the user's left eye is disposed and the second eyepiece 1220 at which the user's right eye is disposed. Although it is illustrated in FIGS. 8 and 9 that the first eyepiece 1210 and the second eyepiece 1220 are disposed separately, the embodiment of the present disclosure is not limited thereto. The first eyepiece 1210 and the second eyepiece 1220 may be combined into one.

In an embodiment, the first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

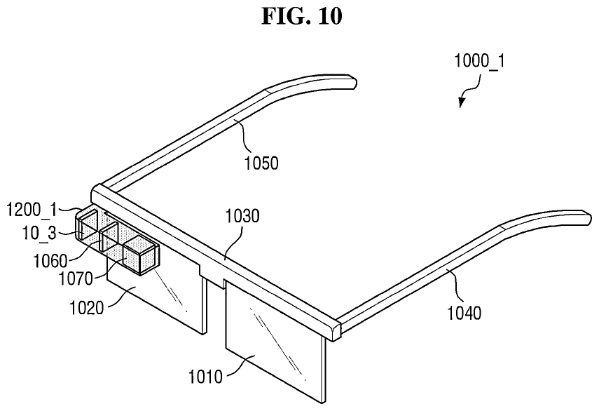

In an embodiment, the head mounted band 1300 serves to fix the display device housing 1100 to the user's head so that a state in which the first and second eyepieces 1210 and 1220, respectively, of the housing cover 1200 are placed over the user's left and right eyes, respectively, can be maintained. When the display device housing 1200 is implemented to be lightweight and compact, the head mounted display device 1000 may be provided with an eyeglass frame as shown in FIG. 10 instead of the head mounted band 800.

In an embodiment, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display device, according to an embodiment.

In an embodiment and referring to FIG. 10, a head mounted display device 1000_1 may be an eyeglasses-type display device in which a display device housing 1200_1 is implemented in a lightweight and compact manner. The head mounted display device 1000_1 according to an embodiment may include a display device 10_3, a left eye lens 1010, a right eye lens 1020, a support frame 1030, temples 1040 and 1050, an optical member 1060, an optical path conversion member 1070, and the display device housing 1200_1.

In an embodiment, the display device housing 1200_1 may include the display device 10_3, the optical member 1060, and the optical path conversion member 1070. The image displayed on the display device 10_3 may be magnified by the optical member 1060 and may be provided to the user's right eye through the right eye lens 1020 after the optical path thereof is converted by the optical path conversion member 1070. As a result, the user may view an augmented reality image, through the right eye, in which a virtual image displayed on the display device 10_3 and a real image seen through the right eye lens 1020 are combined.

Although it is illustrated in FIG. 10 that the display device housing 1200_1 is disposed at the right end of the support frame 1030, the invention is not limited thereto. For example, the display device housing 1200_1 may be disposed at the left end of the support frame 1030, in which case the image of the display device 10_3 may be provided to the user's left eye. In another embodiment, the display housing 1200_1 may be disposed at both the left end and the right end of the support frame 1030, in which case the user may view the image displayed on the display device 10_3 through both the left and right eyes.

The invention should not be construed as being limited to the embodiments set forth herein. Rather, these embodiments are provided so that this disclosure will be thorough and complete and will fully convey the invention to those skilled in the art. While the invention has been particularly shown and described with reference to embodiments thereof, it will be understood by those of ordinary skill in the art that various changes in form and details may be made therein without departing from the spirit or scope of the invention. Moreover, the embodiments or parts of the embodiments may be combined in whole or in part without departing from the scope of the invention.

What is claimed is:

1. A display device comprising:
a substrate;
a transistor disposed on the substrate;
a planarization layer disposed on the transistor;
a first electrode disposed on the planarization layer to be connected to the transistor;
an intermediate layer disposed on the first electrode;
a second electrode disposed on the intermediate layer;
a reflective layer disposed in a trench of the planarization layer and separated from the first electrode; and
a bonding layer disposed between the inner wall of the trench and the reflective layer.

2. The display device of claim 1,
wherein the reflective layer is a floating electrode.

3. The display device of claim 1,
wherein the reflective layer does not overlap the transistor.

4. The display device of claim 1,
further comprising a connection electrode connecting the transistor and the first electrode.

5. The display device of claim 4,
wherein the reflective layer and the connection electrode do not overlap each other.

6. The display device of claim 1,
wherein the bonding layer is in contact with the reflective layer.

7. The display device of claim 1,
wherein the bonding layer includes at least one of a titanium oxide layer, a titanium nitride layer, an Indium Tin Oxide (ITO), an organic layer and an inorganic layer.

8. The display device of claim 4,
further comprising an insulating layer disposed between the reflective layer and the first electrode.

9. The display device of claim 8,
wherein the insulating layer comprises:
a first insulating layer disposed on the reflective layer; and
a second insulating layer disposed on the first insulating layer.

10. The display device of claim 9,
wherein the first electrode is connected to the connection electrode through a contact hole formed in the second insulating layer, the first insulating layer, and the planarization layer.

11. The display device of claim 4,
wherein the connection electrode is connected to one of a source area or a drain area of the transistor.

12. The display device of claim 1,
wherein the planarization layer includes SiOx.

13. The display device of claim 9,
wherein the first insulating layer includes SiNx.

14. The display device of claim 9,
wherein the second insulating layer includes SiOx.

15. The display device of claim 1,
wherein an area of the first electrode is greater than an area of the reflective layer.

16. The display device of claim 15,
wherein, in a plan view, an edge of the reflective layer is surrounded by an edge of the first electrode.

17. The display device of claim 4,
wherein the first electrode is directly connected to the connection electrode.

18. The display device of claim 4,
wherein the first electrode is in direct contact with the connection electrode.

19. The display device of claim 1,
wherein the reflective layer includes Ag.

20. The display device of claim 1,
further comprising a constant voltage line connected to the reflective layer, wherein the constant voltage line transmits a constant voltage.

21. The display device of claim 20,
wherein the constant voltage line is disposed between the substrate and the reflective layer.
